(19) United States
(12) Patent Application Publication
(10) Pub. No.: US 2021/0226083 A1
(43) Pub. Date: Jul. 22, 2021

(54) LIGHT EMITTING UNIT AND MANUFACTURING METHOD THEREOF

(71) Applicant: WUHAN CHINA STAR OPTOELECTRONICS TECHNOLOGY CO., LTD, Wuhan, Hubei (CN)

(72) Inventors: Guiyang ZHANG, Wuhan, Hubei (CN); Guowei ZHA, Wuhan, Hubei (CN); Yong YANG, Wuhan, Hubei (CN)

(21) Appl. No.: 16/308,468

(22) PCT Filed: Sep. 13, 2018
(86) PCT No.: PCT/CN2018/105362

§ 371 Date: Dec. 9, 2018

(30) Foreign Application Priority Data
Aug. 30, 2018 (CN) 201811000766.4

(51) Int. Cl. H01L 33/06; H01L 33/38; H01L 33/00; H01L 33/32; H01L 33/58

(52) U.S. Cl. CPC H01L 33/06; H01L 33/38; H01L 33/58; H01L 33/32; H01L 33/0075

(57) ABSTRACT

A light emitting unit and a manufacturing method thereof are provided. The light emitting unit includes a light emitting diode (LED) chip including a light emitting surface, and an optical functional film disposed on the light emitting surface of the LED chip, where a light transmittance of the optical functional film is greater than 95% in a wavelength range of 350 nm to 480 nm.

### FIELD OF DISCLOSURE

The present disclosure relates to a light emitting unit, and more particularly to a light emitting unit and manufacturing method thereof with a flip-chip light emitting diode.

### BACKGROUND

Light emitting diodes (LEDs) are active light-emitting devices with advantages of small size, light weight, high brightness, long life, and a variety of luminous colors. In 1955, the Radio Corporation of America discovered that gallium arsenide (GaAs) can emit red light. Also, in 1962, a visible light emitting diode was successfully developed. In 1993, a Japanese scientist, Nakamura Shuji, invented blue LEDs based on gallium nitride (GaN) and indium gallium nitride (InGaN). Currently, LEDs have replaced traditional incandescent lamps, tungsten lamps, and fluorescent lamps, and are widely used in lighting, billboards, traffic lights, car lights, and backlights.

In order to achieve RGB full color display, a white backlight is usually used. A white LED can be composed of three primary LEDs including LED (R), LED (G), and LED (B), where (R), (G), and (B) are primary colors of red, green, and blue. Alternatively, referring to FIG. 1, which shows a schematic diagram of a white light LED 10 of the prior art. The white light LED 10 includes a drive substrate 11, a reflecting layer 12, a plurality of blue light LEDs 13 in a parallel arrangement, and a yellow fluorescent film 14. A principle of illumination of the white light LED 10 is that by disposing a yellow fluorescent film 14 above the blue light LED 13, the light emitted by the blue light LED 13 is mixed while passing through the yellow fluorescent film 14 to emit white light. The white light LED 10 has advantages of simple structure, low cost, easy adjustment of color, high reliability, and can be used for different shapes for displaying, and thus is widely used in various backlight modules.

Although a backlight module using the white light LED 10 has many advantages, the blue light emitted by the blue light LED 13 will excite red and green lights due to the blue light is applied to red and green quantum dots of the yellow fluorescent film 14. These red and green lights are easily scattered and reflected when passing through other layers. Moreover, when these red and green lights are incident on the blue light LED 13, a sapphire substrate (refractive index of about 1.76) on the blue light LED 13 has a low reflectance to light. Specifically, please refer to FIG. 2, which shows a graph of reflectivity of a sapphire substrate in air with different incident angles. It can be seen from FIG. 2 that only a small portion of light is reflected from a surface of the sapphire substrate, and most of light is absorbed by internal structures (e.g., a multiple quantum well structure, a carrier doped layer, etc.) of the white light LED 10 by a non-radiative transition, so that the luminous efficiency of the backlight module will decrease.

### SUMMARY OF THE DISCLOSURE

In order to solve technical problems mentioned above, an object of the present disclosure is to provide a light emitting unit and manufacturing method thereof, by optically designing an optical functional film is formed on a light emitting surface of an LED (such as a surface of a sapphire substrate), which can reflect red and green light, thereby increasing overall luminous efficiency of the backlight module.

In order to achieve the objects described above, the present disclosure provides a light emitting unit including: a light emitting diode (LED) chip, including: a substrate including a light emitting surface and a light incident surface opposite to the light emitting surface; a n-type gallium nitride layer disposed on the light incident surface of the substrate; a multiple quantum well structure disposed on the n-type gallium nitride layer; a p-type gallium nitride layer disposed on the multiple quantum well structure, and the multiple quantum well structure located between the n-type gallium nitride layer and the p-type gallium nitride layer; a negative electrode disposed on the n-type gallium nitride layer; and a positive electrode disposed over the p-type gallium nitride layer; and a blue light transmission film disposed on the light emitting surface of the LED chip, where a light transmittance of the blue light transmission film is greater than 95% at a wavelength range of 350 nm to 480 nm, and a thickness of the blue light transmission film is less than 25 μm.

In one preferred embodiment of the present disclosure, the blue light transmission film is a multilayer structure, and a material of the blue light transmission film is an inorganic compound, and the multilayer structure is selected from a group of a silicon dioxide layer, a zinc sulfide layer, a zirconium dioxide layer, a tantalum pentoxide layer, a niobium pentoxide layer, a titanium dioxide layer, an aluminum oxide layer, an indium tin oxide layer, and a magnesium fluoride layer.

The present disclosure also provides a light emitting unit, including: a light emitting diode (LED) chip including a light emitting surface; and an optical functional film disposed on the light emitting surface of the LED chip, where a light transmittance of the optical functional film is greater than 95% at a wavelength range of 350 nm to 480 nm.

In one preferred embodiment of the present disclosure, the optical functional film includes a blue light transmission film.

In one preferred embodiment of the present disclosure, the optical functional film is a multilayer structure, and a material of the optical functional film is an inorganic compound.

In one preferred embodiment of the present disclosure, the multilayer structure is selected from a group of a silicon dioxide layer, a zinc sulfide layer, a zirconium dioxide layer, a tantalum pentoxide layer, a niobium pentoxide layer, a titanium dioxide layer, an aluminum oxide layer, an indium tin oxide layer, and a magnesium fluoride layer.

In one preferred embodiment of the present disclosure, the LED chip is a flip LED chip.

In one preferred embodiment of the present disclosure, the LED chip includes: a substrate including the light emitting surface and a light incident surface opposite to the light emitting surface; a n-type gallium nitride layer disposed on the light incident surface of the substrate; a multiple quantum well structure disposed on the n-type gallium nitride layer; a p-type gallium nitride layer disposed on the multiple quantum well structure, and the multiple quantum well structure located between the n-type gallium nitride layer and the p-type gallium nitride layer; a negative electrode disposed on the n-type gallium nitride layer; and a positive electrode disposed over the p-type gallium nitride layer.

In one preferred embodiment of the present disclosure, the LED chip further includes: a metal layer disposed between the p-type gallium nitride layer and the positive electrode; and an isolation layer disposed on the metal layer, the negative electrode, and the positive electrode, where the isolation layer is configured to electrically isolate the negative electrode from the positive electrode.

In one preferred embodiment of the present disclosure, a material of the substrate includes sapphire.

In one preferred embodiment of the present disclosure, a thickness of the optical functional film is less than 25 μm.

The present disclosure also provides a method for manufacturing a light emitting unit, including: providing a substrate, and defining a light emitting surface and a light incident surface on the substrate; forming an optical functional film on the light emitting surface of the substrate, where a light transmittance of the optical functional film is greater than 95% at a wavelength range of 350 nm to 480 nm; and sequentially forming a n-type gallium nitride layer, a multiple quantum well structure, a p-type gallium nitride layer, a negative electrode, and a positive electrode on the light incident surface of the substrate, so that a light emitting diode (LED) chip is formed.

In one preferred embodiment of the present disclosure, the step of forming the LED chip includes: disposing the n-type gallium nitride layer on the light incident surface of the substrate; disposing the multiple quantum well structure on the n-type gallium nitride layer; disposing the p-type gallium nitride layer on the multiple quantum well structure, where the multiple quantum well structure is located between the n-type gallium nitride layer and the p-type gallium nitride layer; disposing the negative electrode on the n-type gallium nitride layer; and disposing the positive electrode over the p-type gallium nitride layer.

In one preferred embodiment of the present disclosure, the step of forming the LED chip further includes: disposing a metal layer between the p-type gallium nitride layer and the positive electrode; and disposing an isolation layer on the metal layer, the negative electrode, and the positive electrode, where the isolation layer is configured to electrically isolate the negative electrode from the positive electrode.

In comparison to prior art, the present disclosure provides an optical functional film on the light emitting surface of the LED without changing the conventional LED fabrication process. In use, the blue light emitted by the LED passes through the optical functional film and enters the yellow fluorescent film to excite red and green lights, and the optical functional film can reflect these red and green lights, thereby reducing re-absorption of the red and green lights by the LED, and improving overall luminous efficiency of the backlight module. In addition, the optical functional film can also protect the light emitting surface of the LED. The improvement of the luminous efficiency of the backlight module also means that the product's performance is improved, which is conducive to enhancing a competitiveness of the product in the market.

### BRIEF DESCRIPTION OF THE DRAWINGS

FIG. 1 shows a schematic diagram of a white light LED of the prior art.

FIG. 2 shows a graph of reflectivity of a sapphire substrate in air with different incident angles.

FIG. 3 shows a schematic diagram of a light emitting unit according to a preferred embodiment of the present disclosure.

FIG. 4 shows a flow chart of a method of manufacturing a light emitting unit according to a preferred embodiment of the present disclosure.

FIG. 5 is a graph showing transmittance of an optical functional film of FIG. 3 corresponding to wavelengths.

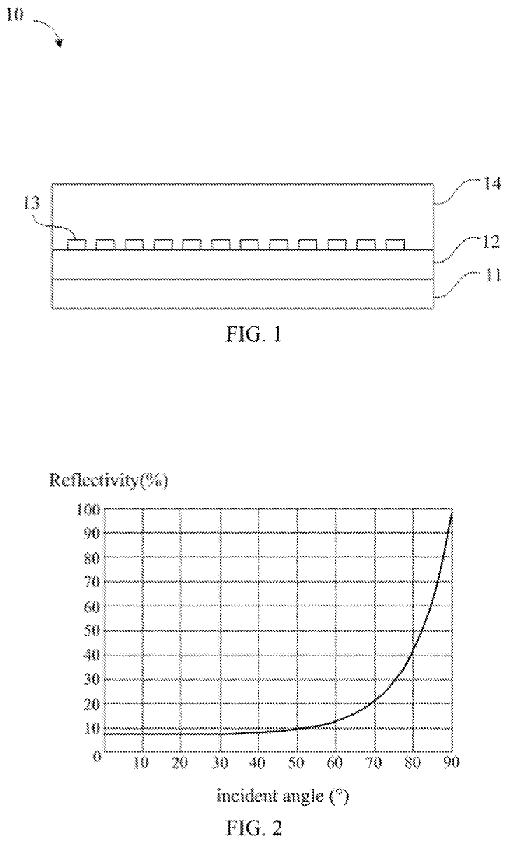

### DETAILED DESCRIPTION

The structure and the technical means adopted by the present disclosure to achieve the above and other objects can be best understood by referring to the following detailed description of the preferred embodiments and the accompanying drawings.

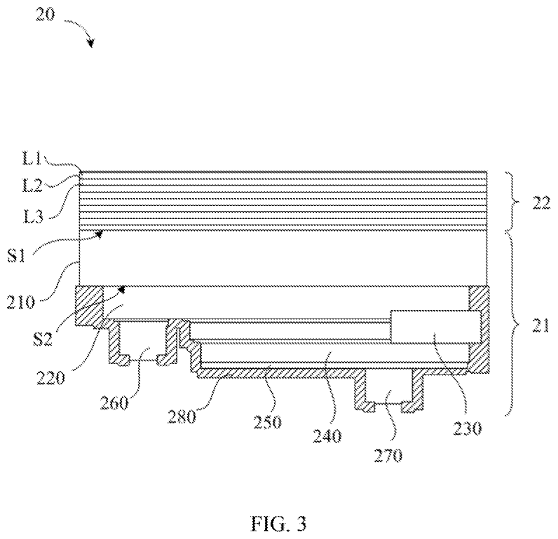

Referring to FIG. 3, which shows a schematic diagram of a light emitting unit according to a preferred embodiment of the present disclosure. A light emitting unit 20 includes a LED chip 21 and an optical functional film 22. The light emitting unit 20 is a light source capable of emitting blue light. By disposing a yellow fluorescent film above the light emitting unit 20, the light emitted by the light emitting unit 20 is mixed while passing through the yellow fluorescent film to emit white light. In the present disclosure, the optical functional film 22 is prepared on a light emitting surface S1 of the LED chip 21 by optical design without changing the manufacturing process of the conventional LED chip 21, and the specific structure and manufacturing method will be detailed later. When the light emitting unit 20 is disposed in a backlight module, the blue light emitted by the LED chip 21 passes through the optical functional film 22 and enters the yellow fluorescent film, and then the blue light will excite red and green lights due to the blue light is applied to red and green quantum dots. The optical functional film 22 can reflect these red and green lights, thereby reducing re-absorption of the red and green lights by the LED chip 21, and improving overall luminous efficiency of the backlight module. Additionally, the optical functional film 22 can also protect the light emitting surface S1 of the LED chip 21.

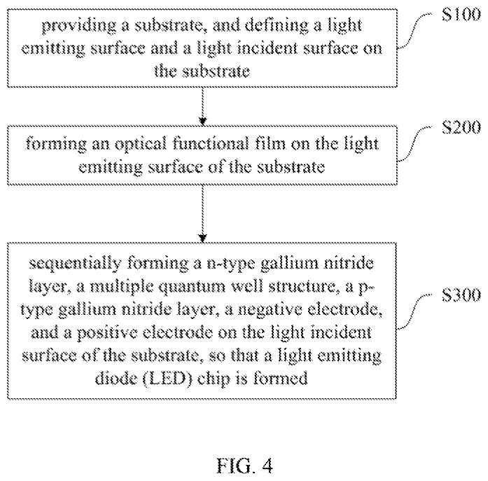

Referring to FIG. 3 and FIG. 4, where FIG. 4 shows a flow chart of a method of manufacturing a light emitting unit 20 according to a preferred embodiment of the present disclosure. In the manufacturing method of the light emitting unit 20 of the present disclosure, firstly, step S100 is performed to provide a substrate 210, and to define a light emitting surface S1 and a light incident surface S2 on the substrate 210. Preferably, a material of the substrate 210 material includes sapphire.

As shown in FIG. 3 and FIG. 4, next, proceeding to step S200, an optical functional film 22 is disposed on the light emitting surface S1 of the substrate 210. The optical functional film 22 is a multilayer structure including a first layer L1, a second layer L2, a third layer L3, and so on. A material of the optical functional film 22 is preferably an inorganic compound. The optical functional film 22 can be formed by layer-by-layer deposition by vacuum evaporation or magnetron sputtering, and a thickness of each layer is precisely controlled according to optical simulation results and by adjusting coating parameters. Preferably, a total thickness of the optical functional film 22 is less than 25 micrometers, so as to avoid decreasing an optical performance of the light emitting unit 20. Moreover, the optical functional film 22 can improve the white light emitting performance of the light emitting unit 20, and can also protect the light emitting surface of the LED chip 210. Optionally, the multilayer structure of the optical functional film 22 is selected from a group of a silicon dioxide (SiO₂) layer, a zinc sulfide (ZnS) layer, a zirconium dioxide (ZrO₂) layer, a tantalum pentoxide (Ta₂O₅) layer, a niobium pentoxide (Nb₂O₅) layer, a titanium dioxide (TiO₂) layer, an aluminum oxide (Al₂O₃) layer, an indium tin oxide (ITO) layer, and a magnesium fluoride (MgF₂) layer.

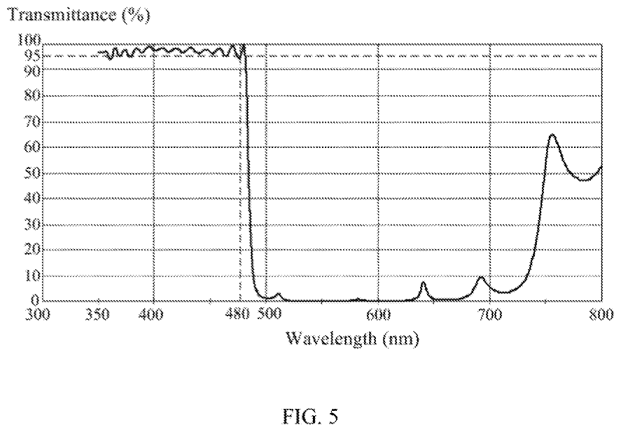

Referring to FIG. 5, which is a graph showing transmittance of an optical functional film of FIG. 3 corresponding to wavelengths. When the optical functional film 22 of FIG. 3 is implemented by a blue light transmission film (BLTF), a light transmittance of the optical functional film 22 is greater than 95% in a wavelength range of 350 nm to 480 nm (as shown in FIG. 5). Also, as shown in FIG. 5, in addition to individual wavelength bands, the long-wavelength (red and green lights) has a reflectance greater than 95%. On the basis of ensuring that the optical functional film 22 has high blue light transmission, the absorption of the LED chip 210 of the light emitting unit 20 of FIG. 3 on red and green lights is avoided. That is, the optical functional film 22 reflects red and green lights, thereby reducing the re-absorption of red and green lights by the light emitting unit 20. Therefore, when the light emitting unit 20 is disposed in the backlight module, the overall luminous efficiency of the backlight module can increase.

As shown in FIG. 3 and FIG. 4, next, step S300 is performed, by means of metal-organic chemical vapor deposition (MOCVD), electron beam evaporation, ion beam etching, electron beam etching, etc., a n-type gallium nitride layer 220, a multiple quantum well structure 230, a p-type gallium nitride layer 240, a metal layer 250, a negative electrode 260, a positive electrode 270, and an isolation layer 280 are sequentially formed on the light incident surface S2 of the substrate 210, such that the LED chip 210 is formed. Specifically, firstly, the n-type gallium nitride layer 220 is disposed on the light incident surface S2 of the substrate 210. Next, the multiple quantum well structure 230 is disposed on the n-type gallium nitride layer 220. Next, the p-type gallium nitride layer 240 is disposed on the multiple quantum well structure 230, where the multiple quantum well structure 230 is located between the n-type gallium nitride layer 220 and the p-type gallium nitride layer 240. Next, the metal layer 250 is disposed on the p-type gallium nitride layer 240. Next, the negative electrode 260 is disposed on the n-type gallium nitride layer 220. Next, the positive electrode 270 is disposed on the metal layer 250, so the metal layer 250 will be located between the p-type gallium nitride layer 240 and the positive electrode 270, such that p-type gallium nitride layer 240 is electrically contacted with the positive electrode 270. Next, the isolation layer 280 is disposed on the metal layer 250, the negative electrode 260, and the positive electrode 270, where the isolation layer 280 is configured to electrically isolate the negative electrode 260 from the positive electrode 270. In the present embodiment, the LED chip 210 is a flip LED chip, but is not limited thereto. As can be seen from the above, the presence of the optical functional film 22 does not change the conventional fabrication process of the LED chip 210. After the light emitting unit 20 is manufactured through the above steps, the produced light emitting unit 20 performs a binning (BIN) measurement. The light emitting unit 20 is driven by a certain voltage and current, and the light emitting power and the light emitting wavelength of the light emitting unit 20 are detected, and the light emitting unit 20 of the same specification (e.g., at a certain luminous power, a fluctuation range of a luminous power is less than 3%, and at a certain wavelength, a fluctuation range of the wavelength is less than 1 nm) is separated by a splitting method and placed on the same blue film. Finally, the light emitting unit 20 is packaged and stored in a warehouse.

In conclusion, the present disclosure provides an optical functional film on the light emitting surface of the LED without changing the conventional LED fabrication process. In use, the blue light emitted by the LED passes through the optical functional film and enters the yellow fluorescent film to excite red and green lights, and the optical functional film can reflect these red and green lights, thereby reducing re-absorption of the red and green lights by the LED, and improving overall luminous efficiency of the backlight module. In addition, the optical functional film can also protect the light emitting surface of the LED. The improvement of the luminous efficiency of the backlight module also means that the product's performance is improved, which is conducive to enhancing competitiveness of the product in the market.

The above descriptions are merely preferable embodiments of the present disclosure. Any modification or replacement made by those skilled in the art without departing from the principle of the present disclosure should fall within the protection scope of the present disclosure.

What is claimed is:

1. A light emitting unit, comprising:
a light emitting diode (LED) chip, comprising:
a substrate comprising a light emitting surface and a light incident surface opposite to the light emitting surface;
a n-type gallium nitride layer disposed on the light incident surface of the substrate;
a multiple quantum well structure disposed on the n-type gallium nitride layer;
a p-type gallium nitride layer disposed on the multiple quantum well structure, and the multiple quantum well structure located between the n-type gallium nitride layer and the p-type gallium nitride layer;
a negative electrode disposed on the n-type gallium nitride layer; and
a positive electrode disposed over the p-type gallium nitride layer; and
a blue light transmission film disposed on the light emitting surface of the LED chip, wherein a light transmittance of the blue light transmission film is greater than 95% in a wavelength range of 350 nm to 480 nm, and a thickness of the blue light transmission film is less than 25 μm.

2. The light emitting unit as claimed in claim 1, wherein the blue light transmission film is a multilayer structure, and a material of the blue light transmission film is an inorganic compound, and the multilayer structure is selected from a group of a silicon dioxide layer, a zinc sulfide layer, a zirconium dioxide layer, a tantalum pentoxide layer, a niobium pentoxide layer, a titanium dioxide layer, an aluminum oxide layer, an indium tin oxide layer, and a magnesium fluoride layer.

3. A light emitting unit, comprising:
a light emitting diode (LED) chip comprising a light emitting surface; and
an optical functional film disposed on the light emitting surface of the LED chip, wherein a light transmittance of the optical functional film is greater than 95% in a wavelength range of 350 nm to 480 nm.

4. The light emitting unit as claimed in claim 3, wherein the optical functional film comprises a blue light transmission film.

5. The light emitting unit as claimed in claim 3, wherein the optical functional film is a multilayer structure, and a material of the optical functional film is an inorganic compound.

6. The light emitting unit as claimed in claim 5, wherein the multilayer structure is selected from a group of a silicon dioxide layer, a zinc sulfide layer, a zirconium dioxide layer, a tantalum pentoxide layer, a niobium pentoxide layer, a titanium dioxide layer, an aluminum oxide layer, an indium tin oxide layer, and a magnesium fluoride layer.

7. The light emitting unit as claimed in claim 3, wherein the LED chip is a flip LED chip.

8. The light emitting unit as claimed in claim 3, wherein the LED chip comprises:
a substrate comprising the light emitting surface and a light incident surface opposite to the light emitting surface;
a n-type gallium nitride layer disposed on the light incident surface of the substrate;
a multiple quantum well structure disposed on the n-type gallium nitride layer;
a p-type gallium nitride layer disposed on the multiple quantum well structure, and the multiple quantum well structure located between the n-type gallium nitride layer and the p-type gallium nitride layer;
a negative electrode disposed on the n-type gallium nitride layer; and
a positive electrode disposed over the p-type gallium nitride layer.

9. The light emitting unit as claimed in claim 8, wherein the LED chip further comprises:
a metal layer disposed between the p-type gallium nitride layer and the positive electrode; and
an isolation layer disposed on the metal layer, the negative electrode, and the positive electrode, wherein the isolation layer is configured to electrically isolate the negative electrode from the positive electrode.

10. The light emitting unit as claimed in claim 8, wherein a material of the substrate comprises sapphire.

11. The light emitting unit as claimed in claim 3, wherein a thickness of the optical functional film is less than 25 μm.

12. A method for manufacturing a light emitting unit, comprising:
providing a substrate, and defining a light emitting surface and a light incident surface on the substrate;
forming an optical functional film on the light emitting surface of the substrate, wherein a light transmittance of the optical functional film is greater than 95% in a wavelength range of 350 nm to 480 nm; and
sequentially forming a n-type gallium nitride layer, a multiple quantum well structure, a p-type gallium nitride layer, a negative electrode, and a positive electrode on the light incident surface of the substrate, so that a light emitting diode (LED) chip is formed.

13. The method for manufacturing the light emitting unit as claimed in claim 12, wherein the optical functional film comprises a blue light transmission film.

14. The method for manufacturing the light emitting unit as claimed in claim 12, wherein the optical functional film is a multilayer structure, and a material of the optical functional film is an inorganic compound.

15. The method for manufacturing the light emitting unit as claimed in claim 14, wherein the multilayer structure is selected from a group of a silicon dioxide layer, a zinc sulfide layer, a zirconium dioxide layer, a tantalum pentoxide layer, a niobium pentoxide layer, a titanium dioxide layer, an aluminum oxide layer, an indium tin oxide layer, and a magnesium fluoride layer.

16. The method for manufacturing the light emitting unit as claimed in claim 12, wherein the LED chip is a flip LED chip.

17. The method for manufacturing the light emitting unit as claimed in claim 12, wherein a material of the substrate comprises sapphire.

18. The method for manufacturing the light emitting unit as claimed in claim 12, wherein a thickness of the optical functional film is less than 25 μm.

19. The method for manufacturing the light emitting unit as claimed in claim 12, wherein the step of forming the LED chip comprises:
disposing the n-type gallium nitride layer on the light incident surface of the substrate;
disposing the multiple quantum well structure on the n-type gallium nitride layer;
disposing the p-type gallium nitride layer on the multiple quantum well structure, wherein the multiple quantum well structure is located between the n-type gallium nitride layer and the p-type gallium nitride layer;
disposing the negative electrode on the n-type gallium nitride layer; and
disposing the positive electrode over the p-type gallium nitride layer.

20. The method for manufacturing the light emitting unit as claimed in claim 19, wherein the step of forming the LED chip further comprises:
disposing a metal layer between the p-type gallium nitride layer and the positive electrode; and
disposing an isolation layer on the metal layer, the negative electrode, and the positive electrode, wherein the isolation layer is configured to electrically isolate the negative electrode from the positive electrode.
